(19) United States
(12) Patent Application Publication
(10) Pub. No.: US 2025/0359225 A1
(43) Pub. Date: Nov. 20, 2025

(54) LINER FOR PMOSFET SOURCE DRAIN

(71) Applicant: Taiwan Semiconductor Manufacturing Company, Ltd., Hsin-Chu (TW)

(72) Inventors: Sheng-Syun Wong, Hsinchu County (TW); Shih-Chieh Chang, Taipei City (TW)

(21) Appl. No.: 19/283,459

(22) Filed: Jul. 29, 2025

Related U.S. Application Data
(63) Continuation of application No. 18/431,043, filed on Feb. 2, 2024.
(60) Provisional application No. 63/610,034, filed on Dec. 14, 2023.

(51) Int. Cl. H10D 62/13; H10D 30/01; H10D 30/43; H10D 30/67; H10D 62/10; H10D 64/01

(52) U.S. Cl. CPC H10D 62/151; H10D 30/014; H10D 30/43; H10D 30/6735; H10D 62/121; H10D 64/017

(57) ABSTRACT

A semiconductor structure according to the present disclosure includes a substrate, a first source/drain feature and a second source/drain feature disposed over the substrate, and a plurality of nanostructures extending between the first source/drain feature and the second source/drain feature. Each of the first source/drain feature and the second source/drain feature includes a first epitaxial layer in contact with sidewalls of the plurality of nanostructures and a second epitaxial layer spaced apart from the sidewalls of the plurality of nanostructures by the first epitaxial layer. The first epitaxial layer includes a semiconductor material doped with carbon (C) and boron (B).

### PRIORITY DATA

This application is a continuation of U.S. Non-Provisional application Ser. No. 18/431,043, filed Feb. 2, 2024, which claims priority to U.S. Provisional Patent Application No. 63/610,034, filed Dec. 14, 2023, each of which is hereby incorporated by reference in its entirety for all purposes.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor. The channel region of a GAA transistor may be formed from nanowires, nanosheets, other nanostructures, and/or other suitable structures.

GAA transistors may be fabricated using a gate-last process. A dummy gate stack is formed over a channel region when the source/drain features are formed. After the source/drain features are formed, the dummy gate stack is removed and channel layers in the channel region are released as suspended channel members. A functional gate structure is then formed to wrap around each of the suspended channel members. The removal of the dummy gate stack and the release of the channel members require more than one etching steps.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2-16 illustrate fragmentary cross-sectional views of a workpiece during a fabrication process according to the method of FIG. 1, according to one or more aspects of the present disclosure.

FIG. 17 illustrates an enlarged fragmentary cross-sectional view of the first epitaxial layer in FIG. 14, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

With the continuous scaling down of semiconductor devices, GAA transistors may replace FinFETs for smaller technology nodes to provide better electrostatics and short channel control. In a gate last process to fabricate a GAA transistor, the dummy gate stack (also referred to as a poly gate stack) may be removed by an etchant containing ammonium hydroxide. This etchant may cause damages to silicon channel members and source/drain features due to leak of the etchant through weak points between the gate spacer layer and the topmost channel members. This leak may result in damages to the p-type source/drain features, which may include silicon germanium. The p-type source/drain feature may have a leakage path through the underlying bulk substrate. Additionally, the p-type dopant in the p-type source/drain feature may out-diffuse into the bulk substrate to worsen the leakage.

The present disclosure includes a process that deposits a protective epitaxial layer over sidewalls the channel members and a top surface of the underlying substrate. In some embodiments, the protective epitaxial layer covers weak points and cracks and reduces leakage into the substrate. In some instances, the protective epitaxial layer may include a semiconductor material doped with carbon (C) and boron (B).

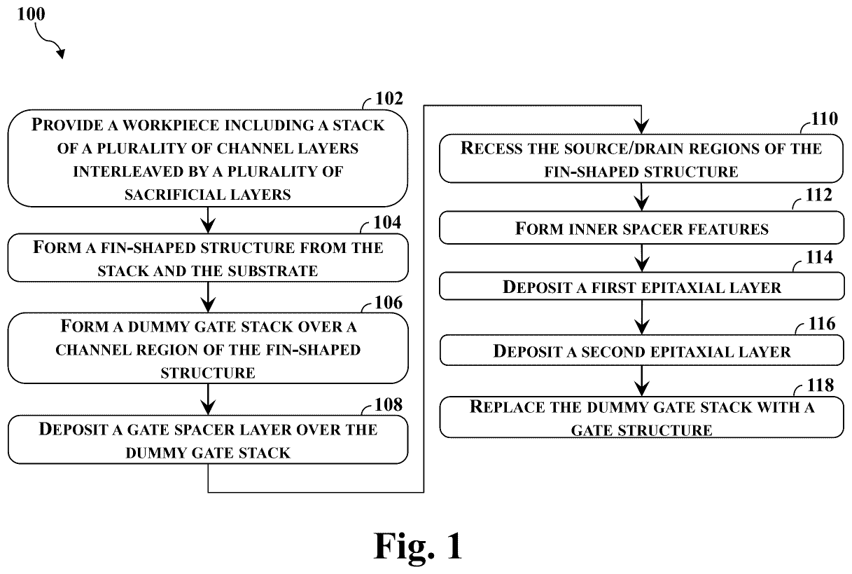

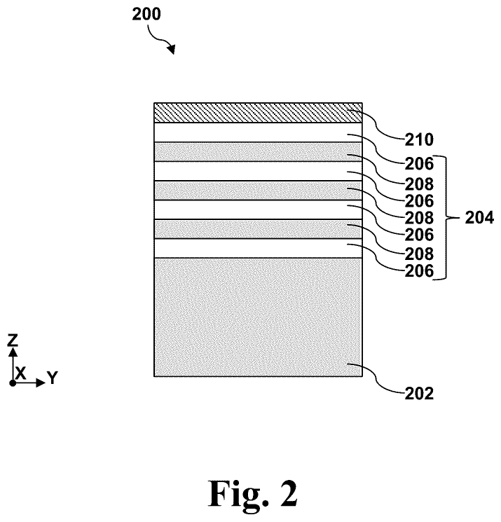

The various aspects of the present disclosure will now be described in more detail with reference to the figures. In that regard, FIG. 1 is a flowchart illustrating a method 100 of forming a semiconductor structure from a workpiece according to embodiments of the present disclosure. Method 100 is merely an example and is not intended to limit the present disclosure to what is explicitly illustrated in method 100. Additional steps can be provided before, during and after the method 100, and some steps described can be replaced, eliminated, or moved around for additional embodiments of the method. Not all steps are described herein in detail for reasons of simplicity. Method 100 is described below in conjunction with FIG. 2-17, which are fragmentary cross-sectional views of workpiece 200 at different stages of fabrication according to embodiments of the method 100 in FIG. 1. Because the workpiece 200 will be fabricated into a semiconductor structure or a semiconductor device, the workpiece 200 may be referred to herein as a semiconductor structure or a semiconductor device 200 as the context requires. For avoidance, the X, Y and Z directions in FIGS. 2-17 are perpendicular to one another. Throughout the present disclosure, unless expressly otherwise described, like reference numerals denote like features.

Referring to FIGS. 1 and 2, method 100 includes a block 102 where a stack 204 of alternating semiconductor layers is formed over the workpiece 200. As shown in FIG. 2, the workpiece 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P) or arsenic (As). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 includes sacrificial layers 206 of a first semiconductor composition interleaved by channel layers 208 of a second semiconductor composition. In other words, the channel layers 208 are interleaved by the sacrificial layers 206. The first and second semiconductor composition may be different. In some embodiments, the sacrificial layers 206 include silicon germanium (SiGe) and the channel layers 208 include silicon (Si). It is noted that four (4) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 2 and 10. In the embodiments represented in FIG. 2, the stack 204 includes a bottommost sacrificial layer 206 and a topmost sacrificial layer 206. In the embodiments, the topmost sacrificial layer 206 functions to protect the topmost channel layer and may be completely removed in subsequent processes.

All sacrificial layers 206 may have a first thickness. In some instances, the first thickness may be between about 4 nm and about 7 nm. The channel layers 208 may have a second thickness greater than the first thickness. In some instances, the second thickness may be between about 8.5 nm and about 10.5 nm. The second thickness is greater because each of the channel layers 208 may also be partially etched when the sacrificial layers are selectively removed to release the channel layers as channel members. While not explicitly illustrated in the figures, the topmost channel layers 208 may have a third thickness greater than the second thickness. In some instances, the third thickness may be between about 10.5 nm and about 12 nm. Because the topmost channel layers 208 is most likely to be subject to damages during the patterning process, the greater third thickness is in place to compensate for the material loss during the process steps.

The sacrificial layers 206 and channel layers 208 in the stack 204 may be deposited using a molecular beam epitaxy (MBE) process, a vapor phase deposition (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204. In some alternative embodiments, the sacrificial layers 206 may include silicon germanium (SiGe) and the channel layers 208 include silicon (Si).

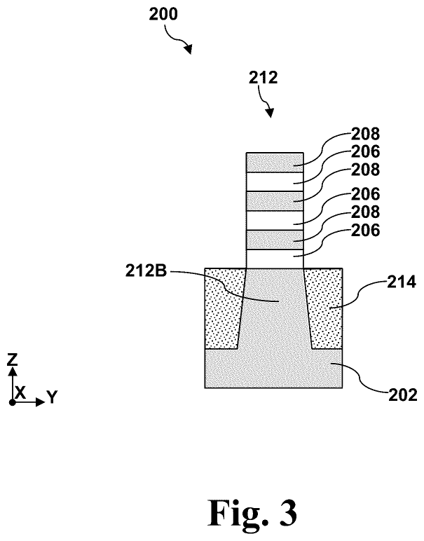

Referring still to FIGS. 1, 2 and 3, method 100 includes a block 104 where a fin-shaped structure 212 is formed from the stack 204 and a portion of the substrate 202. To pattern the stack 204, a hard mask layer 210 (shown in FIG. 2) may be deposited over the stack 204 to form an etch mask. The hard mask layer 210 may be a single layer or a multi-layer. For example, the hard mask layer 210 may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204. As shown in FIG. 3, the fin-shaped structure 212 that includes the sacrificial layers 206 and the channel layers 208 extends vertically along the Z direction and lengthwise along the X direction. As shown in FIG. 3, the fin-shaped structure 212 includes a base fin structure 212B patterned from the substrate 202. The patterned stack 204, including the sacrificial layers 206 and the channel layers 208, is disposed directly over the base fin structure 212B. The base fin structure 212B may also be referred to as a mesa 212B.

An isolation feature 214 is formed adjacent the fin-shaped structure 212. In some embodiments represented in FIG. 3, the isolation feature 214 is disposed on sidewalls of the base fin structure 212B. In some embodiments, the isolation feature 214 may be formed in the trenches to isolate the fin-shaped structures 212 from a neighboring fin-shaped structure. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 3. The fin-shaped structure 212 rises above the STI feature 214 after the recessing, while the base fin structure 212B is embedded or buried in the isolation feature 214.

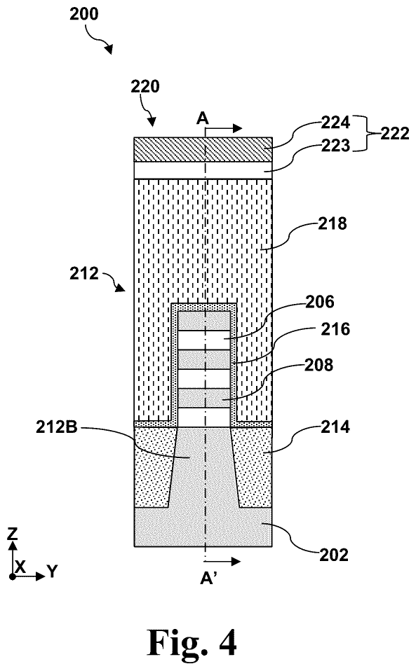

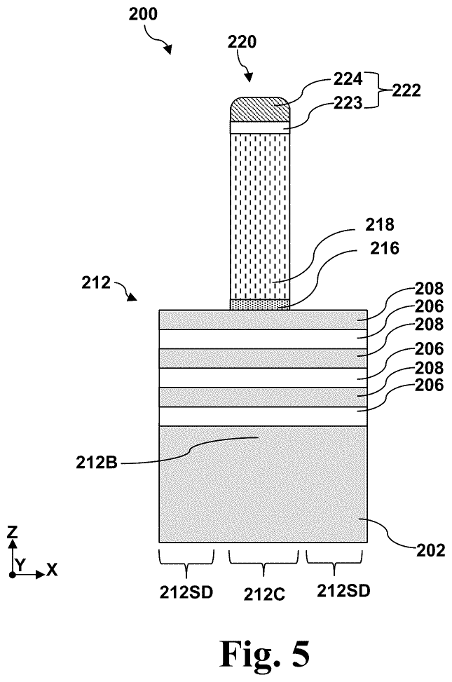

Referring to FIGS. 1, 4 and 5, method 100 includes a block 106 where a dummy gate stack 220 is formed over a channel region 212C of the fin-shaped structure 212. In some embodiments, a gate replacement process (or gate-last process) is adopted where the dummy gate stack 220 (shown in FIGS. 4 and 5) serves as a placeholder to undergo various processes and is to be removed and replaced by a functional gate structure. Other processes and configuration are possible. In some embodiments illustrated in FIG. 5, the dummy gate stack 220 is formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent the source/drain regions 212SD. As shown in FIG. 5, the channel region 212C is disposed between two source/drain regions 212SD along the X direction.

The formation of the dummy gate stack 220 may include deposition of layers in the dummy gate stack 220 and patterning of these layers. Referring to FIG. 4, a dummy dielectric layer 216, a dummy electrode layer 218, and a gate-top hard mask layer 222 may be blanketly deposited over the workpiece 200. In some embodiments, the dummy dielectric layer 216 may be formed on the fin-shaped structure 212 using a chemical vapor deposition (CVD) process, an ALD process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 5. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 5, the dummy gate stack 220 is patterned such that it is only disposed over the channel region 212C, not disposed over the source/drain region 212SD.

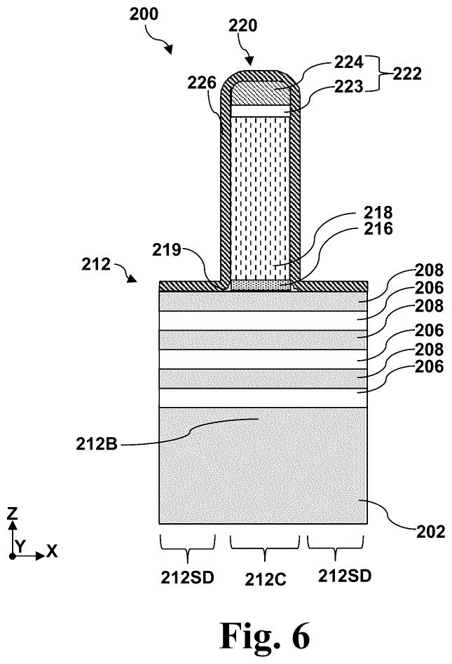

Referring to FIGS. 1 and 6, method 100 includes a block 108 where a gate spacer layer 226 is deposited over the workpiece 200, including over the dummy gate stack 220. In some embodiments, the gate spacer layer 226 is deposited conformally over the workpiece 200, including over top surfaces and sidewalls of the dummy gate stack 220. The term “conformally” may be used herein for ease of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process. As shown in FIG. 6, it has been observed that the gate spacer layer 226 may have a footing profile and does not completely conformally cover corner regions between the dummy dielectric layer 216 and the topmost channel layer 208, thereby leaving behind a void 219. The void 219 may be completely unfilled by the gate spacer layer 226 or incompletely filled by the gate spacer layer 226. The presence of the void 219 weakens the etch resistance of the gate spacer layer 226 around the corner regions.

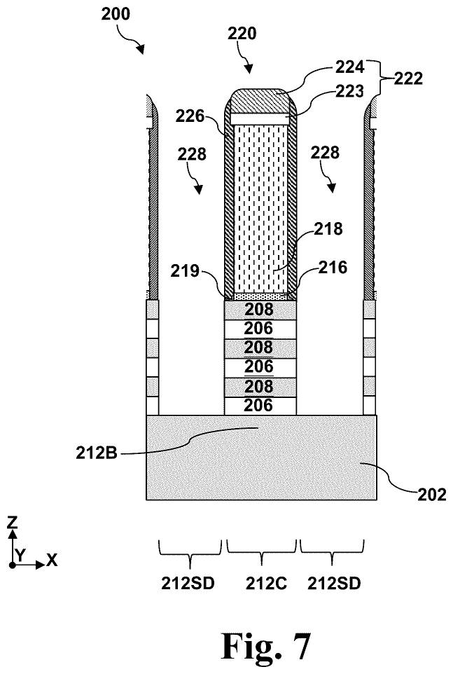

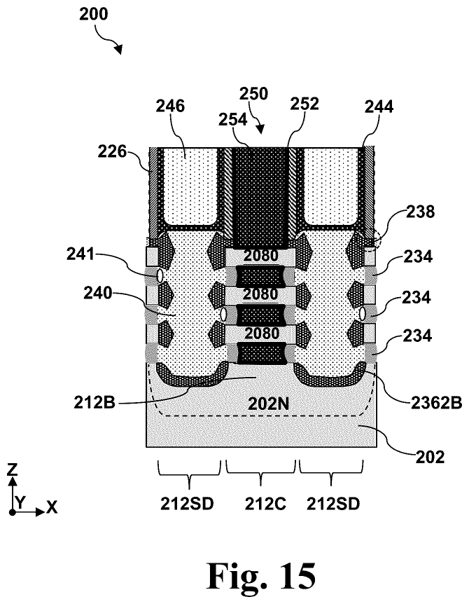

Referring to FIGS. 1 and 7, method 100 includes a block 110 where a source/drain region 212SD of the fin-shaped structure 212 is anisotropically recessed to form a source/drain trench 228. The anisotropic etch may include a dry etch or a suitable etch process that etches the source/drain regions 212SD and a portion of the substrate 202 below the source/drain regions 212SD. The resulting source/drain trench 228 extends vertically through the depth of the stack 204 and partially into the substrate 202. An example dry etch process for block 110 may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. As illustrated in FIG. 7, the source/drain regions 212SD of the fin-shaped structure 212 are recessed to expose sidewalls of the sacrificial layers 206 and the channel layers 208. In some embodiments shown in FIG. 7, the source/drain trenches 228 do not substantially extend below the stack 204 into the substrate 202. In some other embodiments shown in FIG. 15, the source/drain trenches 228 extends through stack 204 and partially into the substrate 202 and the source/drain trenches 228 include bottom surfaces and lower sidewalls defined in the substrate 202. In some embodiments represented in FIG. 7, the voids 219 at the corner regions may only be covered by a thin layer of the gate spacer layer 226.

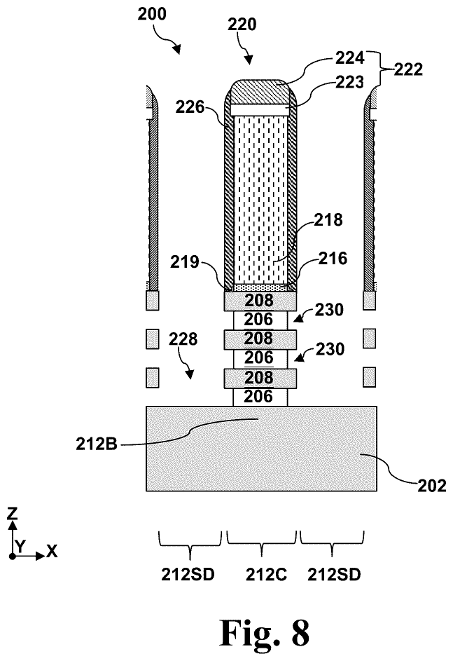

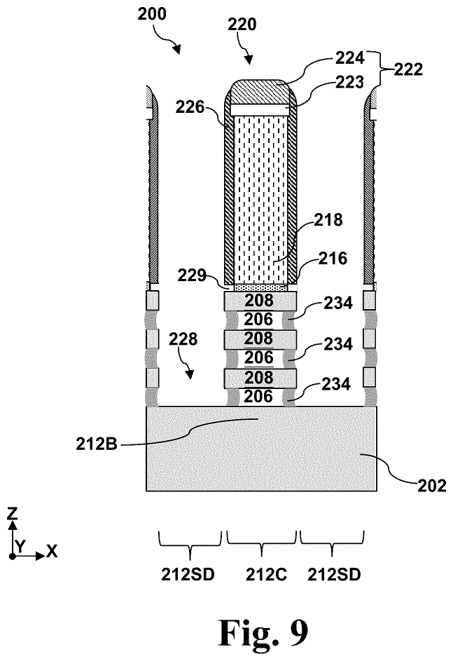

Referring to FIGS. 1, 8 and 9, method 100 includes a block 112 where inner spacer features 234 are formed. Operation at block 112 may include selective and partial removal of the sacrificial layers 206 to form inner spacer recesses 230 (shown in FIG. 8), deposition of inner spacer material over the workpiece 200 (not explicitly shown in figures), and etch back the inner spacer material to form inner spacer features 234 in the inner spacer recesses 230 (shown in FIG. 9). Referring to FIG. 8, the sacrificial layers 206 exposed in the source/drain trenches 228 are selectively and partially recessed to form inner spacer recesses 230 while the gate spacer layer 226, the exposed portion of the substrate 202, and the channel layers 208 are substantially unetched. The recessing to form the inner spacer recesses 230 may further thin or weaken the gate spacer layer 226 that covers the voids 219. In an embodiment where the channel layers 208 consist essentially of silicon (Si) and sacrificial layers 206 consist essentially of silicon germanium (SiGe), the selective recess of the sacrificial layers 206 may be performed using a selective wet etch process or a selective dry etch process. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

After the inner spacer recesses 230 are formed, an inner spacer material is deposited over the workpiece 200, including over the inner spacer recesses 230. The inner spacer material may include silicon oxide, silicon oxycarbonitride, silicon nitride, silicon oxynitride, carbon-rich silicon carbonitride, or a low-k dielectric material. While not explicitly shown, the inner spacer material may be a single layer or a multilayer. In one embodiment, the inner spacer material includes silicon oxycarbonitride. In some implementations, the inner spacer material may be deposited using CVD, PECVD, SACVD, ALD or other suitable methods. The inner spacer material is deposited into the inner spacer recesses 230 as well as over the sidewalls of the channel layers 208 exposed in the source/drain trenches 228. Referring to FIG. 9, the deposited inner spacer material is then etched back to remove the inner spacer material from the sidewalls of the channel layers 208 to form the inner spacer features 234 in the inner spacer recesses 230. At block 112, the inner spacer material may also be removed from the top surfaces and/or sidewalls of the gate-top hard mask layer 222 and the gate spacer layer 226. In some implementations, the etch back operations performed at block 112 may include use of hydrogen fluoride (HF), fluorine gas (F₂), hydrogen (H₂), ammonia (NH₃), nitrogen trifluoride (NF₃), or other fluorine-based etchants. As shown in FIG. 9, each of the inner spacer features 234 is in direct contact with the recessed sacrificial layers 206 and is disposed vertically (along the Z direction) between two neighboring channel layers 208.

While not explicitly shown, before any of the epitaxial layers are formed, method 100 may include a cleaning process to clean surfaces of the workpiece 200. The cleaning process may include a dry clean, a wet clean, or a combination thereof. In some examples, the wet clean may include use of standard clean 1 (RCA SC-1, a mixture of deionized (DI) water, ammonium hydroxide (NH₄OH), and hydrogen peroxide (H₂O₂)), standard clean 2 (RCA SC-2, a mixture of DI water, hydrochloric acid (HCl), and hydrogen peroxide (H₂O₂)), SPM (a sulfuric peroxide mixture), and/or hydrofluoric acid for oxide removal. The dry clean process may include helium (He) and hydrogen (H₂) treatment. The hydrogen treatment may convert silicon on the surface to silane (SiH₄), which may be pumped out for removal.

Reference is made to FIG. 9. The etch back of the inner spacer material and the cleaning process may remove the gate spacer layer 226 that covers the voids 219 and form cracks 229 at an interface between the gate spacer layer 226 and the topmost channel layer 208. In some embodiments represented in FIG. 9, the crack 229 may be defined by a bottom surface of the gate spacer layer 226, a sidewall of the dummy dielectric layer 216, and a top surface of the topmost channel layer 208. The crack 229 reduces structural integrity of the dielectric layers (including the gate spacer layer 226 and the dummy dielectric layer 216) around the dummy gate stack 220 and becomes a weak point.

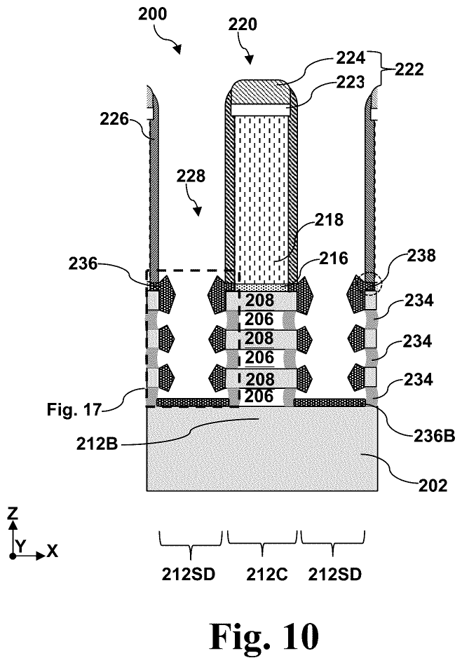

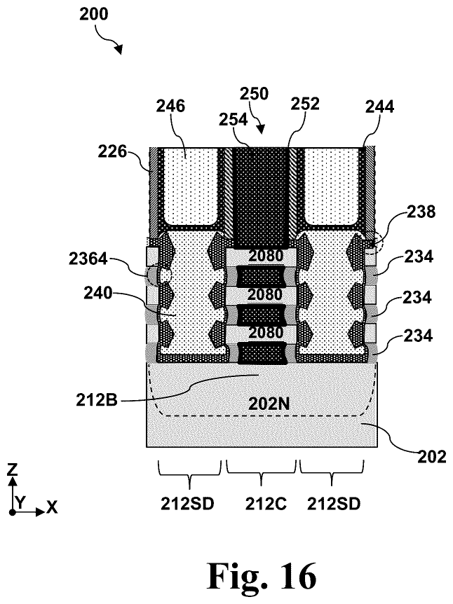

Referring to FIGS. 1 and 10, method 100 includes a block 114 where a first epitaxial layer 236 is selectively deposited over exposed sidewalls of the channel layer 208 and exposed surface of the substrate 202. In some embodiments illustrated in FIG. 10, the first epitaxial layer 236 may be deposited using a growth-etch deposition process or a cyclic deposition process. As its name suggests, the growth-etch deposition process includes a growth component (or growth cycles) and an etch component (or etch cycles). The growth component (or growth cycles) selectively deposits the first epitaxial layer 236 primarily on semiconductor surfaces and the etch component (or etch cycles) removes the first epitaxial layer 236 deposited on non-semiconductor surfaces. In some alternative embodiments illustrated in FIG. 16, the first epitaxial layer 236 may deposited using a straight-up epitaxial deposition process without any etching components. While more of the first epitaxial layer 236 is deposited on semiconductor surfaces, some may be deposited on dielectric surfaces as well. As a result, a thin first epitaxial layer 2364 may be deposited over sidewalls of the inner spacer features 234, as illustrated in FIG. 16. As shown in FIGS. 10 and 16, a filler portion 238 of the first epitaxial layer 236 may fill the crack 229 (shown in FIG. 9) and is in direct contact with the bottom surface of the gate spacer layer 226, the sidewall of the dummy dielectric layer 216, and the top surface of the topmost channel layer 208. The first epitaxial layer 236 also includes a bottom portion 236B disposed on the substrate 202 exposed in the source/drain regions 212SD.

According to the present disclosure, materials for the first epitaxial layer 236 are selected based on at least three criteria. First, it has to include a semiconductor material that can be satisfactorily deposited over surfaces of the channel layers 208. Second, it has to be more etch resistant than the second epitaxial layer 240 during removal of the dummy gate stack 220. Third, the first epitaxial layer 236 should be able to prevent or reduce out-diffusion of dopants in the subsequently-deposited second epitaxial layer 240 into the based fin 212B (i.e., mesa 212B), thereby to reduce leakage. When the second epitaxial layer 240 is a p-type source/drain feature that includes silicon germanium (SiGe) doped with a p-type dopant such as boron (B), the first epitaxial layer 236 may include silicon (Si), silicon germanium (SiGe), or germanium (Ge) doped with both boron (B) and carbon (C). In some implementations, the first epitaxial layer 236 includes silicon (Si) doped with carbon (C) and boron (B), silicon germanium (SiGe) doped with carbon (C) and boron (B), or germanium (Ge) doped with carbon (C) and boron (B). That is, the first epitaxial layer 236 may include SiCB (Si:CB), SiGeCB (SiGe:CB), or GeCB (Ge:CB). The boron (B) dopant serves to make the first epitaxial layer 236 more etch-resistant than the second epitaxial layer 240. To prevent boron (B) out-diffusion, the carbon (C) dopant is added to trap the boron (B) dopant, preventing too much of it from diffusing out of the semiconductor material matrix of the first epitaxial layer 236. In one embodiment, the first epitaxial layer 236 includes carbon and boron doped silicon, where silicon (Si) is more etch resistant than silicon germanium (SiGe) and carbon (C) slows down out-diffusion of boron (B). In some embodiments, a carbon doping concentration in the first epitaxial layer 236 may be between about 1E19 cm−3 and about 1E21 cm−3 (i.e., about 0.02% to about 2%) and a boron doping concentration in the first epitaxial layer 236 may be between about 5E20 cm⁻³ and about 1E22 cm⁻³ (i.e., about 1% to about 20%). Because the first epitaxial layer 236 serves protective and leakage blocking functions, it may also be referred to as a protective epitaxial layer, a blocking epitaxial layer, or a semiconductor liner.

When the first epitaxial layer 236 includes silicon (Si), it may be deposited using chemical vapor deposition (CVD), atomic layer deposition (ALD), VPE, or MBE using dichlorosilane (DCS, SiCl₂H₂) as a silicon source. When the first epitaxial layer 236 includes silicon germanium (SiGe), it may be deposited using dichlorosilane (DCS, SiCl₂H₂) as a silicon source and germane (GeH₄) as a germanium source. When the first epitaxial layer 236 includes germanium (Ge), it may be deposited using germane (GcH₄) as a germanium source. The dopants, including carbon (C) and boron (B), may be in-situ doped using methyl methylene silane (MMS) as a carbon (C) source and diborane (B₂H₆) as a boron (B) source. When a growth-etch process is adopted, the growth components (or growth cycles) may include use of dichlorosilane or germane as the silicon and germanium sources and the etch components (or growth cycles) may include use of hydrogen chloride (HCl) as an etchant and hydrogen (H₂) as a carrier gas.

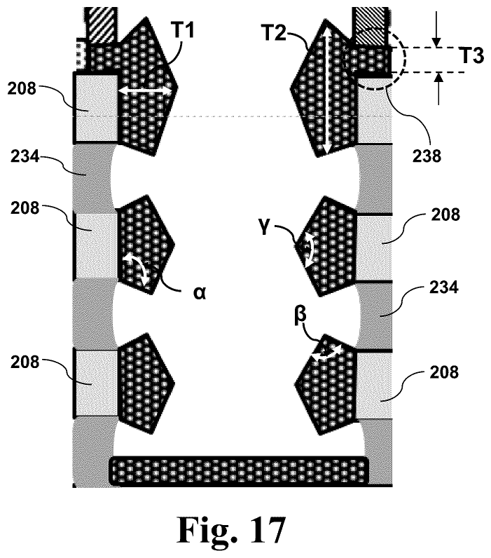

FIG. 17 illustrates an enlarged view of the dotted-line area in FIG. 10. As show in FIG. 17, along the gate-length direction (or Y direction), the first epitaxial layer 236 along sidewalls of the channel layers 208 may exhibit a faceted growth. In some embodiments represented in FIG. 17, the first epitaxial layer 236 grown from a sidewall of a channel layer 208 may have a pentagonal shape or a diamond shape. Each of the pentagonal shapes may have a first thickness T1 measured from a sidewall of the channel layer 208 and a second thickness T2 as measured a thickest portion of the pentagonal shape along the Z direction. In some instances, the first thickness T1 may be between about 5 nm and about 10 nm and the second thickness T2 may be between about 8 nm and about 16 nm. The filler portion 238 of the first epitaxial layer may have a third thickness T3 along the Z direction. The third thickness T3 may be between about 0.1 nm and about 10 nm. The thickness ranges of the first epitaxial layer 236 are not trivial. For example, when the first thickness T1 is smaller than 5 nm, the first epitaxial layer 236 may not provide sufficient protection to the second epitaxial layer 240. When the first thickness T1 is greater than 10 nm, the less conductive first epitaxial layer 236 may unduly increase the contact resistance. Each of the pentagonal shape of the first epitaxial layer 236 includes an angle α between an departing edge and a sidewall of a channel layer 208, an angle β between a departing edge and an extension edge of the pentagonal shape, and an angle γ between two extension edges of the pentagonal shape. In some instances, the angle α may be between about 100° and about 130°, the angle β may be between about 90° and about 130°, and angle γ may be between about 80° and about 160°.

The various attributes of the first epitaxial layer 236 are observable or measurable. For example, carbon doping concentrations, boron doping concentrations, or a composition of the first epitaxial layer 236 may be measured using secondary ion mass spectrometer (SIMS) or energy-dispersive X-ray spectroscopy (EDX). The thicknesses and angles of the diamond shape of the first epitaxial layer 236 may be observed using transmission electron microscope (TEM).

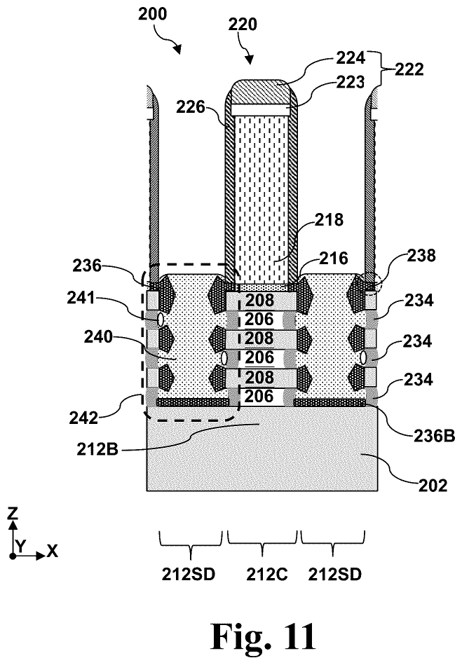

Referring to FIGS. 1 and 11, method 100 includes a block 116 where a second epitaxial layer 240 is deposited over surfaces of the first epitaxial layer 236 and the inner spacer features 234. In some embodiments, the deposition of the second epitaxial layer 240 is performed in situ in the same process chambers as there are less dopant contamination concerns. In some embodiments, the second epitaxial layer 240 may be deposited using vapor-phase epitaxy (VPE), ultra-high vacuum CVD (UHV-CVD), molecular beam epitaxy (MBE), and/or other suitable processes. The second epitaxial layer 240 is a heavily doped semiconductor layer to reduce contact resistance. As shown in FIG. 11, the second epitaxial layer 240 may be deposited on surfaces of the first epitaxial layer 236. In some embodiments, while the second epitaxial layer 240 merges over gaps of the first epitaxial layer 236, gaps 241 may be formed between two adjacent diamond shapes. In some implementations, the second epitaxial layer 240 includes silicon germanium (SiGe) and is doped with a p-type dopant, such as boron (B). A boron (B) doping concentration in the second epitaxial layer 240 may be between about 5E19 cm⁻³ and about 1E20 cm⁻³. Depending on the deposition conditions, the second epitaxial layer 240 may be crystalline or amorphous. When being crystalline, the second epitaxial layer 240 may exert strain on the channel layers 208 to increase carrier mobility. When being amorphous, the second epitaxial layer 240 may exert little or no strain on the channel layers 208. The crystallinity of the second epitaxial layer 240 may be detected using X-ray diffraction (XRD) or reciprocal space mapping (RSM) techniques. The first epitaxial layer 236 and the second epitaxial layer 240 in a source/drain region 212SD may be collectively referred to as a source/drain feature 242. In the depicted embodiments, the source/drain feature 242 is a p-type source/drain feature.

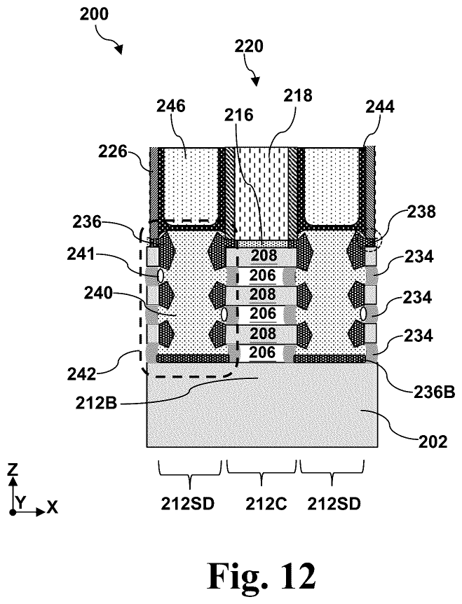

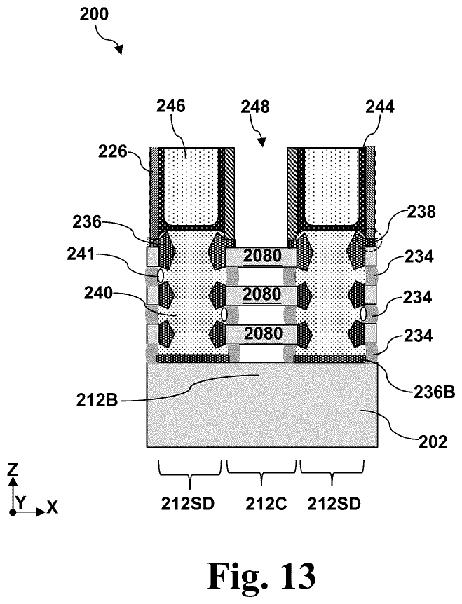

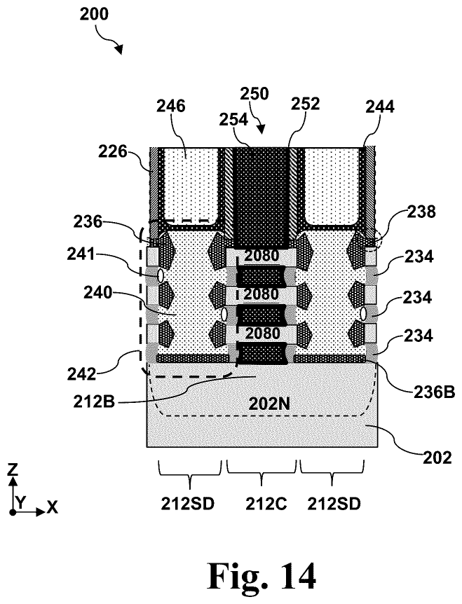

Referring to FIGS. 1 and 12-14, method 100 includes a block 118 where the dummy gate stack 220 is replaced with a gate structure 250. Block 118 may include deposition of a contact etch stop layer (CESL) 244 over the source/drain feature 242 (shown in FIG. 12), deposition of an interlayer dielectric (ILD) layer 246 over the CESL 244 (shown in FIG. 12), removal of the dummy gate stack 220 (shown in FIG. 13), selective removal of the sacrificial layers 206 in the channel region 212C to release the channel layers 208 as channel members 2080 (shown in FIG. 13), and formation of the gate structure 250 to wrap around each of the channel members 2080 (shown in FIG. 14). Referring to FIG. 12, the CESL 244 is deposited over the workpiece 200, including over the source/drain feature 242 and along sidewalls of the gate spacer layer 226. The CESL 244 may include silicon nitride. The ILD layer 246 is then deposited over the CESL 244. In some embodiments, the ILD layer 246 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 246 may be deposited using CVD, FCVD, spin-on coating, or a suitable deposition technique. The CESL may include silicon nitride. After the deposition of the ILD layer 246, the workpiece 200 may be planarized by a planarization process to expose the dummy gate stack 220. For example, the planarization process may include a chemical mechanical planarization (CMP) process. Exposure of the dummy gate stack 220 allows the removal of the dummy gate stack 220.

Referring to FIG. 13, the dummy gate stack 220 is removed. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220. After the removal of the dummy gate stack 220, sidewalls of the channel layers 208 and the sacrificial layers 206 in the channel region 212C are exposed. Referring still to FIG. 13, after the removal of the dummy gate stack 220, the sacrificial layers 206 between the channel layers 208 in the channel region 212C are selectively removed. The selective removal of the sacrificial layers 206 releases the channel layers 208 (shown in FIG. 12) to form suspended channel members 2080 shown in FIG. 13. The selective removal of the sacrificial layers 206 forms a gate trench 248 that includes spaces between adjacent channel members 2080. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). Reference is still made to FIG. 13. The filler portion 238 of the first epitaxial layer 236 plugs in the crack 229 to prevent etchant, such as ammonia hydroxide (NH₄OH), from breaching through the weak point at the crack 229 to cause damages to the second epitaxial layer 240.

Referring to FIG. 14, after the release of the channel members 2080, the gate structure 250 is formed to wrap around each of the channel members 2080. The gate structure 250 includes a gate dielectric layer 252 and a gate electrode 254 over the gate dielectric layer 252. While not explicitly shown, the gate dielectric layer 252 includes an interfacial layer interfacing the channel members 2080 and the mesa 212B and a high-k dielectric layer over the interfacial layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-k dielectric layer may include hafnium oxide. Alternatively, the high-k dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material. The high-k dielectric layer may be formed by ALD, physical vapor deposition (PVD), CVD, oxidation, and/or other suitable methods.

The gate electrode 254 may include a single layer or alternatively a multi-layer structure, such as various combinations of a work function metal layer, a liner layer, a wetting layer, an adhesion layer, a metal fill layer or a metal silicide. By way of example, the gate electrode 254 may include a p-type work function metal layer, such as titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), or nickel silicide (NiSi₂). The gate electrode 254 may also include a metal fill layer such as tungsten (W). In various embodiments, the gate electrode 254 may be formed by ALD, PVD, CVD, e-beam evaporation, or other suitable process. In various embodiments, a CMP process may be performed to remove excessive metal, thereby providing a substantially planar top surface of the gate structure 250. The gate structure 250 includes portions that interpose between channel members 2080 in the channel region 212C. In the depicted embodiments, the semiconductor device 200 shown in FIG. 14 is a p-type GAA transistor. In these embodiments, the source/drain features 242 include boron-doped silicon germanium (SiGe:B), the gate structure 250 includes a p-type work function metal, and channel members 2080 and the source/drain features 242 are disposed over an n-type well 202N.

FIGS. 15-16 illustrate alternative embodiments of the present disclosure. Reference is first made to FIG. 15 where operations at block 110 form a source/drain trench 228 that extends into the substrate 202. As a result, the first epitaxial layer 236 deposited at block 114 may include a curved bottom portion 2362B that extends into the substrate 202. Reference is then made to FIG. 16. When the deposition of the first epitaxial layer 236 at block 114 is performed at a lower temperature, the deposition may become less selective and a thin first epitaxial layer 2364 may be deposited over sidewalls of the inner spacer features 234. The thin first epitaxial layer 2364 has a thickness much smaller than the first thickness T1 of the pentagonal shape shown in FIG. 17. While low temperature deposition of the first epitaxial layer 236 may affect the quality of the first epitaxial layer 236, the presence of the thin first epitaxial layer 2364 may facilitate the deposition of the second epitaxial layer 240 over the inner spacer features 234, thereby preventing the formation of voids 241 shown in FIG. 14.

In one exemplary aspect, the present disclosure is directed to a semiconductor structure. The semiconductor structure includes a substrate, a first source/drain feature and a second source/drain feature disposed over the substrate, and a plurality of nanostructures extending between the first source/drain feature and the second source/drain feature. Each of the first source/drain feature and the second source/drain feature includes a first epitaxial layer in contact with sidewalls of the plurality of nanostructures and a second epitaxial layer spaced apart from the sidewalls of the plurality of nanostructures by the first epitaxial layer. The first epitaxial layer includes a semiconductor material doped with carbon (C) and boron (B).

In some embodiments, the semiconductor material includes silicon (Si), silicon germanium (SiGe), or germanium (Ge). In some embodiments, the first source/drain feature and the second source/drain feature include silicon germanium (SiGe) doped with boron (B). In some implementations, the semiconductor structure further includes a gate structure wrapping around each of the plurality of nanostructures and a gate spacer layer disposed along a sidewall of a portion of the gate structure extending above the plurality of nanostructures. A portion of the first epitaxial layer extends between a top surface of a topmost nanostructure of the plurality of nanostructures and a bottom surface of the gate spacer layer. In some implementations, the portion of the first epitaxial layer includes a thickness between about 0.1 nm and about 1 nm. In some embodiments, a carbon (C) doping concentration in the first epitaxial layer is between about 1E19 cm⁻³ and about 1E21 cm⁻³. In some embodiments, a boron (B) doping concentration in the first epitaxial layer is between about 5E20 cm⁻³ and about 1E22 cm⁻³. In some instances, the semiconductor structure further includes a plurality of inner spacer features interleaving the plurality of nanostructures. A portion of the first epitaxial layer extends over sidewalls of the plurality of inner spacer features.

In another exemplary aspect, the present disclosure is directed to a semiconductor device. The semiconductor device includes a substrate having an n-type well, a source/drain feature disposed over the n-type well, and a plurality of nanostructures extending from and in contact with sidewalls of the source/drain feature. The source/drain feature includes a first epitaxial layer in contact with sidewalls of the plurality of nanostructures and a second epitaxial layer spaced apart from the sidewalls of the plurality of nanostructures by the first epitaxial layer. A portion of the first epitaxial layer is disposed on and in contact with a top surface of a topmost one of the plurality of nanostructures.

In some embodiments, the first epitaxial layer includes a semiconductor material doped with carbon (C) and boron (B). In some embodiments, a carbon (C) doping concentration in the first epitaxial layer is between about 1E19 cm⁻³ and about 1E21 cm⁻³ and a boron (B) doping concentration in the first epitaxial layer is between about 5E20 cm⁻³ and about 1E22 cm⁻³. In some implementations, the semiconductor material includes silicon (Si), silicon germanium (SiGe), or germanium (Ge). In some instances, the source/drain feature includes silicon germanium (SiGe) doped with boron (B). In some embodiments, the semiconductor device further includes a gate structure wrapping around each of the plurality of nanostructures. A portion of the gate structure is disposed over and in contact with the portion of the first epitaxial layer. In some embodiments, the semiconductor device further includes a gate spacer disposed along a sidewall of the gate structure. The portion of the gate structure is sandwiched between the top surface of the topmost one of the plurality of nanostructures and a bottom surface of the gate spacer.

In yet another exemplary aspect, the present disclosure is directed to a method. The method includes forming a fin-shaped structure over a substrate, the fin-shaped structure having a plurality of channel layers interleaved by a plurality of sacrificial layers, forming a dummy gate stack over a channel region of the fin-shaped structure, forming a gate spacer layer along sidewalls of the dummy gate stack, recessing a source/drain region of the fin-shaped structure to form a source/drain recess that extends into the substrate and exposes a portion of the substrate, selectively depositing a first epitaxial layer on sidewalls of the plurality of channel layer and the exposed portion of the substrate, depositing a second epitaxial layer over the first epitaxial layer, removing the dummy gate stack over the channel region of the fin-shaped structure, selectively removing the plurality of sacrificial layers in the channel region to release the plurality of channel layers as a plurality of channel members, and forming a gate structure to wrap around each of the plurality of channel members. The selectively depositing includes use of a semiconductor source, a carbon source, and a boron source.

In some embodiments, the semiconductor source includes dichlorosilane or germane, the carbon source includes methyl methylene silane, and the boron source includes diborane. In some implementations, the removing of the dummy gate stack forms a crack between a top surface of a topmost one of the plurality of channel layers and the gate spacer layer. In some embodiments, the first epitaxial layer includes silicon (Si) doped with carbon (C) and boron (B). In some instances, the removing of the dummy gate stack includes use of ammonium hydroxide.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a substrate;
a source/drain feature disposed over the substrate, wherein the source/drain feature comprises a first epitaxial layer and a second epitaxial layer surrounding the first epitaxial layer; and
a channel layer adjacent to the source/drain feature, wherein a first portion of the first epitaxial layer extends over a top surface of the channel layer.

2. The semiconductor device of claim 1, wherein the first epitaxial layer comprises a semiconductor material doped with boron (B) and carbon (C).

3. The semiconductor device of claim 1, wherein the second epitaxial layer comprises silicon germanium (SiGe) doped with boron (B).

4. The semiconductor device of claim 1, wherein the source/drain feature is configured as a p-type source/drain feature.

5. The semiconductor device of claim 1, further comprising a gate structure disposed over and in contact with the channel layer, wherein the first epitaxial layer is further disposed on a sidewall of the gate structure.

6. The semiconductor device of claim 1, further comprising a gate spacer extending vertically above the channel layer, wherein the first epitaxial layer also extends over a bottom surface of the gate spacer.

7. (canceled)

8. The semiconductor device of claim 1, wherein:
the channel layer is a first channel layer,
the semiconductor device further comprises a second channel layer disposed between the substrate and the first channel layer, and
a second portion of the first epitaxial layer extends along a sidewall but not a top surface of the second channel layer.

9. The semiconductor device of claim 8, further comprising a second epitaxial layer over the first epitaxial layer, wherein a portion of the second epitaxial layer disposed between the first portion and the second portion of the first epitaxial layer comprises a void.

10. A semiconductor device, comprising:
a substrate;
a source/drain feature disposed over the substrate, wherein the source/drain feature comprises a first doped layer and a second doped layer surrounding the first doped layer;
a channel layer adjacent to the source/drain feature, wherein the first doped layer extends over a top surface of the channel layer; and
a gate structure engaging the channel layer, wherein the gate structure directly interfaces with a portion of the first doped layer.

11. The semiconductor device of claim 10, wherein:
the first doped layer comprises a first semiconductor material doped with both boron (B) and carbon (C), and
the second doped layer comprises silicon germanium (SiGe) doped with a p-type dopant.

12. The semiconductor device of claim 11, wherein the first semiconductor material comprises silicon (Si), silicon germanium (SiGe), or germanium (Ge).

13. The semiconductor device of claim 10, wherein the first doped layer further extends along a sidewall of the channel layer.

14. The semiconductor device of claim 10, wherein the first doped layer directly interfaces with a sidewall of the gate structure.

15. The semiconductor device of claim 10, further comprising a gate spacer extending along a sidewall of the gate structure and directly interfacing with the first doped layer.

16. The semiconductor device of claim 10, wherein a bottom portion of the first doped layer extends along a top surface of the substrate.

17. The semiconductor device of claim 10, wherein a bottom portion of the first doped layer extends below a top surface of the substrate and has a curved profile.

18. A method, comprising:
forming a fin structure protruding from a substrate, the fin structure comprising a stack of alternating channel layers and sacrificial layers;
forming a dummy gate stack over a channel region of the fin structure;
forming a gate spacer along a sidewall of the dummy gate stack;
forming a source/drain recess in a source/drain region of the fin structure adjacent to the channel region, the source/drain recess exposing sidewalls of the channel layers and the sacrificial layers;
forming inner spaces on the exposed sidewalls of the sacrificial layers, wherein forming the inner spacers removes a bottom portion of the gate spacer to form a crack that exposes a top surface of a topmost one of the channel layers;
forming a first epitaxial layer on the exposed sidewalls of the channel layers, wherein a portion of the first epitaxial layer is formed in the crack;
forming a second epitaxial layer over the first epitaxial layer in the source/drain recess; and
replacing the dummy gate stack and the sacrificial layers with a gate structure.

19. The method of claim 18, wherein forming the inner spacers comprises:
selectively etching end portions of the sacrificial layers to form inner spacer recesses,
depositing an inner spacer material in the inner spacer recesses,
etching back portions of the inner spacer material to form the inner spacers, wherein the etching back removes the bottom portion of the gate spacer to form the crack.

20. The method of claim 18, wherein forming the first epitaxial layer comprises use of a semiconductor source, a carbon source, and a boron source.

21. The method of claim 18, wherein the crack further exposes a sidewall of the dummy gate stack such that the portion of the first epitaxial layer extends over the sidewall of the dummy gate stack.
